(19) United States
(12) Patent Application Publication
(10) Pub. No.: US 2026/0344256 A1
(43) Pub. Date: Oct. 29, 2026

(54) DISPLAY DEVICE

(71) Applicant: LG Display Co., Ltd., Seoul (KR)

(72) Inventor: Kyungman KIM, Paju-si (KR)

(73) Assignee: LG Display Co., Ltd., Seoul (KR)

(21) Appl. No.: 19/573,343

(22) Filed: Mar. 20, 2026

(30) Foreign Application Priority Data
Apr. 29, 2025 (KR) 10-2025-0056064

(51) Int. Cl. H10K 59/80; H10K 59/122; G09G 3/3233

(52) U.S. Cl. CPC H10K 59/873; H10K 59/122; G09G 3/3233; G09G 2300/0426; G09G 2300/0842; G09G 2354/00

(57) ABSTRACT

A display device can include a substrate, an anode electrode formed on the substrate and patterned in correspondence with a plurality of pixels, a bank formed on the substrate and exposing at least one region of the anode electrode, an emission layer formed on the anode electrode, a cathode electrode formed on the emission layer, and two metal cup structure layers formed on the bank. The metal cup hole can be formed between the two metal cup structure layers spaced apart from each other on the bank.

### CROSS-REFERENCE TO RELATED APPLICATION

The present application claims priority to Korea Patent Application No. 10-2025-0056064, filed in the Republic of Korea on Apr. 29, 2025, the entire contents of which is expressly incorporated by reference herein for all purposes.

### BACKGROUND

The present disclosure relates to a display device.

### DISCUSSION OF THE RELATED ART

With the progress of the information-oriented society, various types of demands for display devices which display an image are increasing, and various types of display devices such as a liquid crystal display device (LCD), a plasma display panel (PDP), and an organic light emitting display device (OLED) have been used.

Among them, the organic light emitting display device includes pixels, and each of the pixels is formed of an organic light emitting element in which an anode electrode, an emission layer, and a cathode electrode are stacked, and a control circuit configured to control an amount of a current applied to the organic light emitting element. Such an organic light emitting element can be vulnerable to an external penetrant such as moisture or oxygen, and thus, cam have a limitation in that it can be easily damaged unless the external contaminants are efficiently blocked.

Recently, a display device implemented as an ultra-thin package and having a higher resolution and display quality is needed. When the display device is miniaturized and the resolution thereof is increased at the same time, an electrical short or a current leakage between pixels adjacent to each other can occur.

### SUMMARY OF THE DISCLOSURE

Embodiments of the present disclosure provide a display device which blocks a path through which moisture or oxygen invades through a metal cup structure layer in an under-cut form.

Embodiments of the present disclosure provide a display device in which a metal cup hole is defined by a blocking layer which is a non-conductive inorganic layer formed on a bank and at least two metal cup structure layers spaced apart from each other on the blocking layer.

Embodiments of the present disclosure provide a display device of which a cathode electrode is configured to receive a low potential driving voltage through a metal cup structure layer.

Embodiments of the present disclosure provide a display device in which a metal cup hole is formed through a connection electrode formed on the same layer as an anode electrode, and at least two metal cup structure layers spaced apart from each other on a bank.

Embodiments of the present disclosure provide a display device in which a metal cup structure layer is connected to a connection electrode through a contact hole formed in a bank and a cathode electrode is configured to receive a low potential driving voltage through the metal cup structure layer and the connection electrode.

Embodiments of the present disclosure provide a display device which prevents invasion of moisture or oxygen into the light emitting element by trapping moisture or oxygen within the metal cup hole.

One embodiment of the present disclosure provides a display device, including a substrate, an anode electrode formed on the substrate and patterned in correspondence with a plurality of pixels, a bank formed on the substrate and exposing at least one region of the anode electrode, an emission layer formed on the anode electrode, a cathode electrode formed on the emission layer, and a metal cup structure layer disposed on the bank.

According to aspects of the present disclosure, a metal cup hole can be formed between two metal cup structure layers spaced apart from each other on the bank.

According to aspects of the present disclosure, the blocking layer can be formed in a mesh form between the two metal cup structure layers to surround each of the plurality of pixels.

According to aspects of the present disclosure, the display device can further include the blocking layer formed on the bank and formed of a non-conductive inorganic material.

According to aspects of the present disclosure, the two metal cup structure layers can be formed to cover one region and another region of the blocking layer, respectively.

According to aspects of the present disclosure, the metal cup hole can be surrounded by the blocking layer and the two metal cup structure layers.

According to aspects of the present disclosure, the display device can further include a spacer formed on the metal cup structure layer.

According to aspects of the present disclosure, the spacer can extend to an upper surface of the bank from an upper surface of the metal cup structure layer.

According to aspects of the present disclosure, the spacer can further extend from the upper surface of the bank to cover a side surface of the bank and an edge of the anode electrode.

According to aspects of the present disclosure, the spacer can be further disposed between the bank and the anode electrode and formed to cover an upper surface of a circuit element layer not covered by the bank and exposed.

According to aspects of the present disclosure, the metal cup structure layer can be electrically connected to a low potential driving voltage, and the cathode electrode can be formed such that at least one region thereof comes into contact with the metal cup structure layer in the metal cup hole.

According to aspects of the present disclosure, the display device can further include a connection electrode formed on the substrate, and the metal cup structure layer can be electrically connected to the connection electrode through a contact hole formed in the bank.

According to aspects of the present disclosure, the connection electrode can be electrically connected to a low potential driving voltage, and the cathode electrode can be formed such that at least one region thereof comes into contact with the metal cup structure layer in the metal cup hole.

According to aspects of the present disclosure, the display device can include a low potential driving voltage line in the form of a shorting bar formed on one side of the substrate, and the metal cup structure layer or the connection electrode can be electrically connected to the low potential driving voltage line in the shorting bar form on the one side of the substrate.

According to aspects of the present disclosure, the metal cup structure layer can include a lower layer formed on the bank; and an upper layer formed on the lower layer, and a lower surface of the upper layer can protrude more outward than an upper surface of the lower layer, and the lower layer and the upper layer can be formed of a conductive inorganic material.

According to aspects of the present disclosure, the emission layer can extend into the metal cup hole, and can be cut around an edge of the upper layer.

According to aspects of the present disclosure, the cathode electrode can extend into the metal cup hole, and can be formed to come into contact with at least one region of the upper layer and the lower layer in the metal cup hole.

Another embodiment of the present disclosure provides a display device, including a substrate on which a plurality of pixels are disposed; a bank formed on the substrate and configured to define the plurality of pixels; and a metal cup structure layer disposed on the bank.

According to aspects of the present disclosure, a metal cup hole can be formed between two metal cup structure layers adjacent to each other on the bank.

According to aspects of the present disclosure, the display device can further include a blocking layer formed on the bank and formed in a mesh form to surround each of the plurality of pixels, and the two metal cup structure layers adjacent to each other can be formed to cover one region and another region of the blocking layer, respectively.

According to aspects of the present disclosure, the metal cup hole can be surrounded by the blocking layer and the two metal cup structure layers adjacent to each other.

According to aspects of the present disclosure, the display device can further include a connection electrode formed on the substrate, and the metal cup structure layers can be electrically connected to the connection electrode through a contact hole formed in the bank.

According to aspects of the present disclosure, the display device can further include a spacer formed on the metal cup structure layer, and the spacer can extend to an upper surface of the bank from an upper surface of the metal cup structure layer.

According to aspects of the present disclosure, the spacer can further extend to a side surface of the bank from the upper surface of the bank and can be formed to cover an upper surface of a circuit element layer not covered by the bank and exposed.

A display device according to embodiments of the present disclosure can prevent the light emitting element from being damaged by moisture or oxygen invading from the outside, through a metal cup hole formed by a metal cup structure layer.

A display device according to embodiments of the present disclosure can prevent IR drop of a low potential driving voltage applied to a cathode electrode, improve device reliability and luminance deviation between pixels by increasing a surface contact between the metal cup structure layer and the cathode electrode.

A display device according to embodiments of the present disclosure can prevent a leakage current on a side surface between pixel columns adjacent to each other, by disposing a blocking layer and a metal cup structure layer between the pixel columns adjacent to each other.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a block diagram of a configuration of a display device according to an embodiment of the present disclosure.

FIG. 2 is a circuit diagram of a pixel according to an embodiment of the present disclosure.

FIG. 3 is a schematic plan view of a display panel according to a first embodiment of the present disclosure.

FIG. 4 is an example of a cross-sectional view taken along I-I’ line illustrated in FIG. 3.

FIG. 5 is another example of a cross-sectional view taken along I-I’ line illustrated in FIG. 3.

FIG. 6 is a schematic plan view of a display panel according to a second embodiment of the present disclosure.

FIG. 7 is an example of a cross-sectional view taken along II-II’ line illustrated in FIG. 6.

FIG. 8 is a schematic plan view of a display panel according to a third embodiment of the present disclosure.

FIG. 9 is an example of a cross-sectional view taken along III-III’ line illustrated in FIG. 8.

FIGS. 10A-0F are views illustrating a method for manufacturing a display panel illustrated in FIG. 9 according to an embodiment of the present disclosure.

FIG. 11 is a view illustrating an electrical connection relationship of a low potential driving voltage line according to an embodiment of the present disclosure.

### DETAILED DESCRIPTION OF THE EMBODIMENTS

Hereinafter, embodiments of the present disclosure will be described with reference to the drawings. In this specification, when it is mentioned that a component (or, an area, a layer, a part, etc.) is referred to as being “on”, “connected to” or “combined to” another component, this means that the component can be directly on, connected to, or combined to the other component or a third component therebetween can be present.

Like reference numerals refer to like elements. Additionally, in the drawings, the thicknesses, proportions, and dimensions of components are exaggerated for effective description. The term “and/or” includes all of one or more combinations defined by related components.

It will be understood that when the terms such as “first” and “second” are used herein to describe various components, these components should not be limited by these terms. The above terms are used only to distinguish one component from another. For example, a first component can be referred to as a second component and vice versa without departing from the scope of the present disclosure. Singular expressions and terms used herein also encompass or include plural expressions and terms, unless the context clearly indicates otherwise.

In addition, terms such as “below”, “the lower side”, “on”, and “the upper side” are used to describe a relationship of configurations shown in the drawing. The terms are described as a relative concept based on a direction shown in the drawing.

In various embodiments of the present disclosure, the terms such as “include,” “comprise,” “including,” or “comprising,” specifies a property, a fixed number, a step, a process, an element and/or a component, or a combination thereof, but does not exclude presence or addition of other properties, fixed numbers, steps, processes, elements and/or components, or a combination thereof. Further, the term “can” fully encompasses all the meanings and coverages of the term “may.”

All the components of each display device/apparatus according to all embodiments of the present disclosure are operatively coupled and configured.

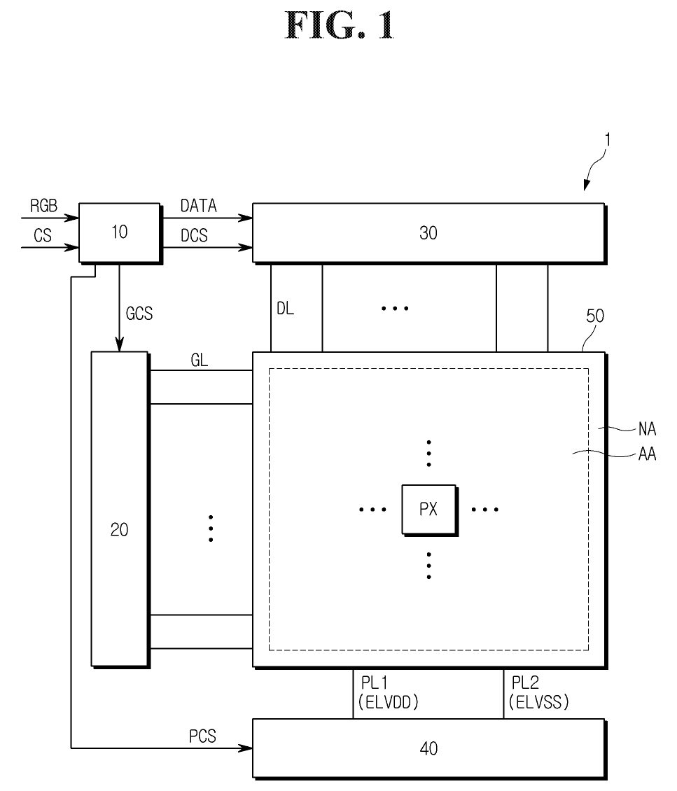

FIG. 1 is a block diagram of a configuration of a display device according to an embodiment of the present disclosure.

Referring to FIG. 1, a display device 1 can include a timing controller 10, a gate driver 20, a data driver 30, a power supply unit 40, and a display panel 50.

The timing controller 10 can be coupled to various processors, for example, a microprocessor, a mobile processor, an application processor, etc., according to a mounted device.

The timing controller 10 can receive a video signal RGB and a control signal CS from an external host system and the like. The video signal RGB can include a plurality of grayscale data. The control signal CS can include, for example, a horizontal synchronization signal, a vertical synchronization signal and a main clock signal.

The timing controller 10 processes the video signal RGB and the control signal CS to be suitable to operational conditions of the display panel 50, and can generate and output image data DATA, a gate driving control signal GCS, a data driving control signal DCS, and a power supply control signal PCS.

The gate driver 20 can be formed in a gate-in-panel manner in which the gate driver 20 is mounted in the display panel 50. The gate driver 20 can be disposed on one side of the display panel 50, or on both sides (for example, a left side and a right side) of the display panel 50 as illustrated. According to a driving method, a panel design method, and the like, the gate driver 20 can be disposed on both sides (for example, a left side and a right side) of the display panel 50 as illustrated, or can be connected to two or more side surfaces among four side surfaces of the display panel 50.

The gate driver 20 can generate scan signals based on a gate driving control signal GCS output from the timing controller 10. The gate driver 20 can provide the generated scan signals to the pixels PX through a plurality of gate lines GL.

In an embodiment of the present disclosure, one pixel PX can be configured to receive a plurality of scan signals having different waveforms. In such an embodiment, the gate driver 20 can provide the plurality of scan signals to the pixels PX through the gate lines GL corresponding thereto, respectively.

The data driver 30 can generate data signals based on the data driving control signal DCS and image data DATA output from the timing controller 10. The data driver 30 can provide the generated data signals to the pixels PX through a plurality of data lines DL.

The power supply unit 40 can generate a high potential driving voltage ELVDD and a low potential driving voltage ELVSS to be provided to the display panel 50 based on the power supply control signal PCS. The power supply unit 40 can provide the generated driving voltages ELVDD and ELVSS to the pixels PX through corresponding voltage lines PL1 and PL2. In addition, the power supply unit 40 can further generate a reference voltage and the like required for driving the pixel PX, and provide it to the pixels PX through a corresponding voltage line.

The display panel 50 can be implemented as a transmissive or a non-transmissive display panel. The transmissive display panel can be applied to a transparent display device of which an image is displayed in the screen and a real background object is visible.

The display panel 50 can be manufactured as a flexible display panel. The flexible display panel can be implemented as an OLED panel which uses a plastic substrate.

The display panel 50 can include a display region AA (or active area) and a non-display region NA (or non-active area) around the display region AA. In an embodiment of the present disclosure, the non-display region NA can be formed to surround the display region AA, and can correspond to a bezel region, but is not limited thereto.

In the display region AA, a plurality of pixels PX (or referred to as sub-pixels) are disposed. The pixels PX can be disposed, for example, in a matrix form in the display region AA. The pixels disposed in one pixel row are connected to the same gate line GL, and the pixels PX disposed in one pixel column are connected to the same data line DL. The pixels PX can emit light at luminance corresponding to a data signal and a scan signal supplied through the gate line GL and the data line DL.

Each pixel PX can include the light emitting element and a driving circuit configured to drive the light emitting element. The light emitting element included in the pixel PX can display one color among red, green and blue.

In another embodiment of the present disclosure, the light emitting element can display one color among cyan, magenta and yellow. In various embodiments of the present disclosure, the light emitting element can display one color among red, green, blue and white.

In an embodiment of the present disclosure, a touch sensor can be further disposed on the display panel 50. A touch input can be sensed using touch sensors or can be sensed through pixels PX. The touch sensors can be disposed on the display panel 50 in an on-cell type or an add-on type, or can be implemented as in-cell type touch sensors embedded to the display panel 50.

The timing controller 10, the gate driver 20, the data driver 30 and the power supply unit 40 can be configured as separate Integrated Circuits (IC) or at least some parts thereof together can be integrated into and form the Integrated Circuit.

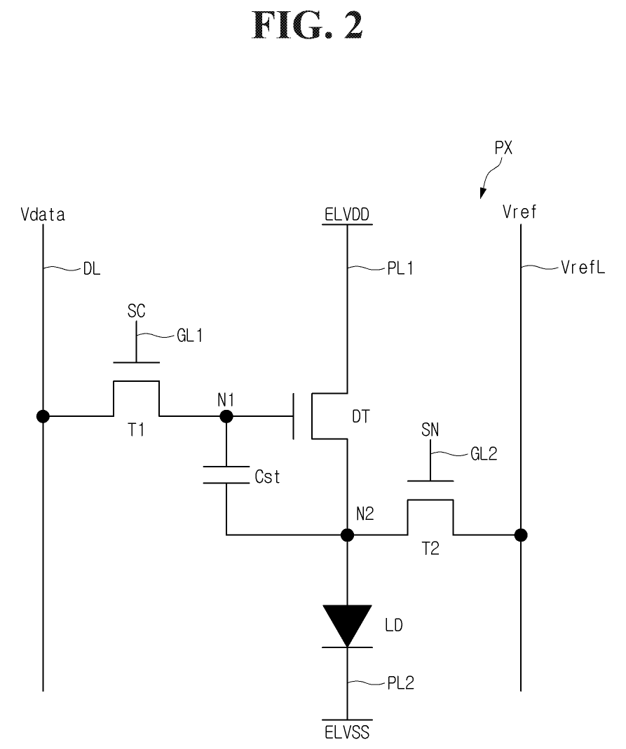

FIG. 2 is a circuit diagram of the pixel according to an embodiment of the present disclosure.

Referring to FIG. 2, the pixel PX according to an embodiment of the present disclosure can include a driving transistor DT, a light emitting element LD connected to the driving transistor DT, and a control circuit configured to control an amount of a driving current to be applied to the light emitting element LD through the driving transistor DT. For example, the control circuit can include first and second transistors T1 and T2, and a storage capacitor Cst.

A first electrode of the driving transistor DT is configured to receive a high potential driving voltage ELVDD (connected to a high potential driving voltage line PL1), and a second electrode thereof is connected to the light emitting element LD through a second node N2. A gate electrode of the driving transistor DT is connected to the data line DL through a first node N1. The driving transistor DT can be turned on according to a voltage difference between the first node N1 and the second node N2 (for example, a gate-source voltage) and can control an amount of the driving current flowing to the light emitting element LD.

A first electrode of the first transistor T1 can be connected to the data line DL and a second electrode thereof can be connected to a gate electrode of the driving transistor DT. A gate electrode of the first transistor T1 can be connected to a first gate line GL1, and can receive a first gate signal. The first gate signal is a scan signal SC, and can be a control signal applied so as to program a data voltage Vdata into the pixel PX.

The first transistor T1 can be turned on according to the scan signal SC applied to the first gate line GL1, and can transfer a data voltage Vdata applied to the data line DL to the first node N1. Such a first transistor T1 can be referred to as a switching transistor.

A first electrode of the second transistor T2 is connected to a reference voltage line VrefL, and a second electrode thereof is connected to the second node N2. A gate electrode of the second transistor T2 can be connected to a second gate line GL2 and can receive a second gate signal. A second gate signal is a sensing signal SN, and can be a control signal applied so as to apply a reference voltage to the pixel PX, or sense an electric characteristic of the pixel PX.

The second transistor T2 can be turned on according to the sensing signal SN applied to the second gate line GL2, and can electrically connect the reference voltage line VrefL and the second node N2 to each other. When the reference voltage Vref is applied to the reference voltage line VrefL, the reference voltage Vref can be applied to the second node N2 through the second transistor T2 turned on.

When the reference voltage line VrefL is not connected to the reference voltage Vref, a sensing signal (for example, a current, a voltage) applied to the second node N2 can flow through the reference voltage line VrefL to be transferred to the data driver 30 (FIG. 1) and/or the timing controller 10 (FIG. 1) etc.

The transferred sensing signal can be used to sense an electric characteristic of the pixel PX. Such a second transistor T2 can be referred to as an initialization transistor and/or a sensing transistor.

The storage capacitor Cst is connected between the first node N1 and the second node N2. The storage capacitor Cst can store a voltage corresponding to a voltage difference between the first node N1 and the second node N2, and maintain the stored voltage during one frame period, thereby stabilizing a voltage of the gate electrode (for example, the first node N1) of the driving transistor DT.

The anode electrode of the light emitting element LD can be connected to the driving transistor DT through the second node N2, and the cathode electrode thereof can be connected to the low potential driving voltage ELVSS (connected to the low potential driving voltage line PL2). When the driving transistor DT is turned on, a current path is formed between the high potential driving voltage ELVDD and the low potential driving voltage ELVSS, and a driving current can flow to the light emitting element LD. The light emitting element LD can emit light at luminance corresponding to an amount of the driving current applied thereto.

In the embodiment of the present disclosure illustrated in FIG. 2, the pixel PX can include an oxide semiconductor transistor. The oxide semiconductor transistor includes a gate electrode, a source electrode, and a drain electrode. The oxide semiconductor transistor has an active layer formed of an oxide semiconductor.

Here, the oxide semiconductor can be set as an amorphous oxide semiconductor or a crystalline oxide semiconductor. The oxide semiconductor transistor can be configured as an n-type transistor. The oxide semiconductor transistor can be formed through a low temperature process and has a lower charge mobility than that of the LTPS transistor. Such an oxide semiconductor transistor has an excellent off current characteristic.

In another embodiment of the present disclosure, the pixel PX can be a hybrid type further including the LTPS (Low Temperature Poly-Silicon) transistor.

The LTPS transistor includes a gate electrode, a source electrode, and a drain electrode. The LTPS transistor includes an active layer formed of poly silicon. Such an LTPS transistor can be configured as a P-type transistor or an N-type transistor. The LTPS transistor has a high electron mobility, and therefore, has a fast driving characteristic.

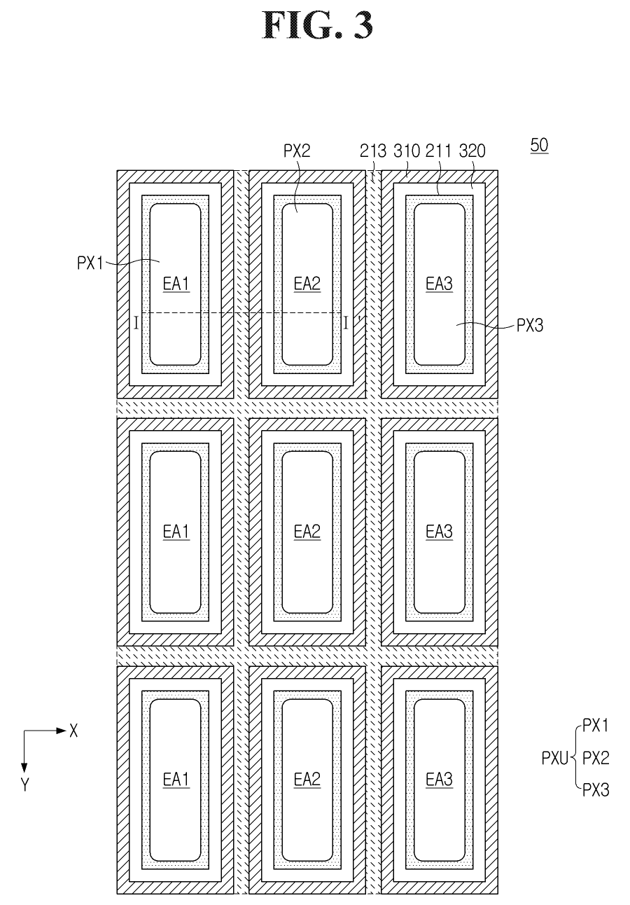

FIG. 3 is a schematic plan view of a display panel according to a first embodiment of the present disclosure. In FIG. 3, a portion of the display region AA (FIG. 1) in which the pixels PX1, PX2 and PX3 are disposed is illustrated.

Referring to FIG. 3, the display panel 50 according to an embodiment of the present disclosure includes a plurality of unit pixels PXU. Each of the unit pixels PXU can include a plurality of pixels PX1, PX2, and PX3 configured to emit light in colors different from one another. In an embodiment of the present disclosure, the plurality of pixels PX1, PX2 and PX3 can display one color among red, green and blue. However, the embodiment is not limited thereto.

In an embodiment of the present disclosure, the pixels PX1, PX2 and PX3 forming one unit pixel PXU and configured to emit light in colors different from one another can be alternately disposed along a first direction X. In addition, the pixels PX1, PX2 and PX3 configured to emit light in the same color can be disposed along a second direction Y generally perpendicular to the first direction.

Each of the pixels PX1, PX2 and PX3 can include emission regions EA1, EA2 and EA3 corresponding thereto, respectively. Each of the emission regions EA1, EA2 and EA3 can be regions in which an anode electrode, an emission layer and a cathode electrode of the light emitting element LD (FIG. 2) are in contact with one another and are stacked.

Each of the emission regions EA1, EA2 and EA3 can be surrounded by a bank 211 defining the emission regions EA1, EA2 and EA3. The bank 211 can be formed in a mesh form surrounding each of the emission regions EA1, EA2 and EA3.

The bank 211 can be formed on the anode electrode and can include an opening which exposes one region of the anode electrode. The exposed region of the anode electrode not covered by the bank 211 can be defined as the emission regions EA1, EA2 and EA3. The bank 211 can be formed to define each of the pixels PX1, PX2 and PX3. For example, pixel rows and pixel columns adjacent to each other can be divided by the bank 211.

A blocking layer 213 and a metal cup structure layer 310 can be formed on the bank 211.

The blocking layer 213 can be formed in at least one region of the bank 211. For example, the blocking layer 213 can extend along the bank 211 along the first direction X. Alternatively, the blocking layer 213 can have a mesh form extending in the first direction X and the second direction Y along the bank 211, but is not limited thereto.

The metal cup structure layer 310 can be formed on the bank 211 such that at least one region thereof covers the blocking layer 213. For example, the metal cup structure layer 310 can be formed to cover at least a portion of an edge of the blocking layer 213 and exposes a center region of the blocking layer 213.

In an embodiment of the present disclosure, at least two metal cup structure layers 310 can be provided between the pixel rows and/or pixel columns adjacent to each other. The at least two metal cup structure layers 310 can be spaced apart from each other at a predetermined interval. At this instance, each of the metal cup structure layers 310 can be configured such that at least one region thereof covers the blocking layer 213. For example, the metal cup structure layers 310 can be configured such that one metal cup structure layer 310 covers at least a portion of an edge on one side of the blocking layer 213, and the other metal cup structure layer 310 covers at least a portion of an edge on the other side of the blocking layer 213. However, the embodiment of the present disclosure is not limited thereto.

The metal cup structure layer 310 can have a form extending along the second direction Y between the pixel columns adjacent to each other. Alternatively, the metal cup structure layer 310 can have a mesh form extending further along the first direction X between pixel rows adjacent to each other, but is not limited thereto.

Structures of the blocking layer 213 and the metal cup structure layer 310 in detail will be described with reference to the drawings below.

A portion of an upper surface of the bank 211 and a portion of an upper surface of the metal cup structure layer 310 can be covered by the spacer 320. In an embodiment of the present disclosure, the spacer 320 can be disposed farther from each of the emission regions EA1, EA2 and EA3 than the bank 211. However, the embodiment of the present disclosure is not limited thereto, and in another embodiment of the present disclosure, the spacer 320 can be disposed more adjacent to each the emission regions EA1, EA2 and EA3 than the bank 211, and can be formed to surround each of the emission regions EA1, EA2 and EA3.

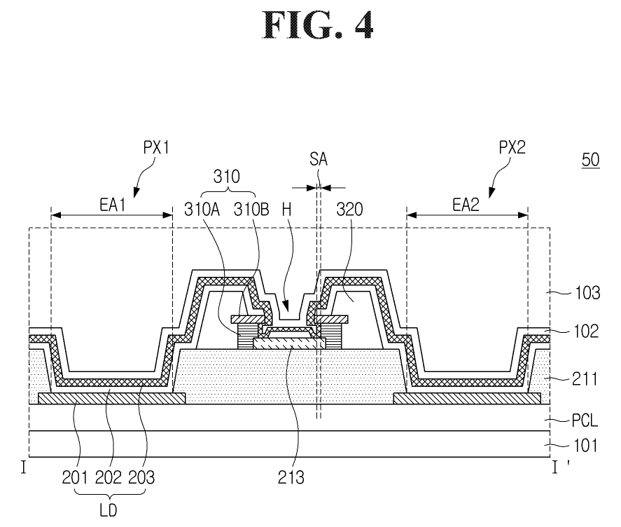

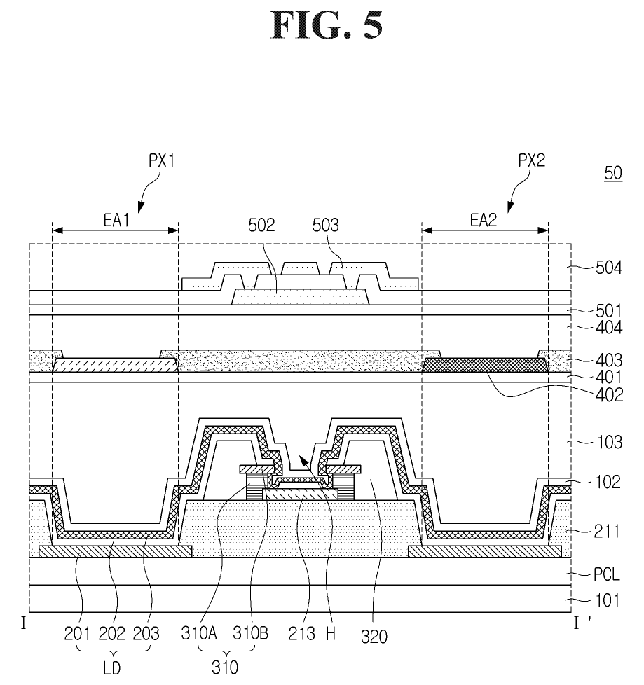

FIG. 4 is an example of a cross-sectional view taken along I-I’ line illustrated in FIG. 3.

Referring to FIG. 4, the display panel 50 according to an embodiment of the present disclosure can include a substrate 101 and pixels PX1 and PX2 disposed on the substrate 101.

The substrate 101 supports various components of the display panel 50. The substrate 101 can be formed of a transparent insulation material such as glass, plastic, and the like. When the substrate 101 is formed of plastic, the substrate 101 can be referred to as a plastic film or a plastic substrate.

For example, the substrate 101 can be in a film form which includes one among polyimide polymer, polyester polymer, silicon polymer, acrylic polymer, polyolefin polymer, and a copolymer thereof, but the embodiments of the present disclosure are not limited thereto. Further, when the substrate 101 is made of plastic, the substrate 101 can be formed in a dual structure. For example, the substrate 101 can have a dual structure having an adhesive layer interposed between a first polyimide layer and a second polyimide layer. For example, the substrate 101 can have a structure which includes an inter-layer insulating layer formed of an inorganic insulation material and interposed between the first polyimide layer and the second polyimide layer.

When the substrate 101 is made of glass, the substrate 101 can be referred to as a glass substrate. For example, the glass substrate can include a shielding metal, and can serve to protect the device from external light or signal interference.

A circuit element layer PCL can be disposed on the substrate 101. In the circuit element layer PCL, circuit elements such as at least one transistors DT, T1 and T2 and a capacitor Cst described with reference to FIG. 2 can be disposed. For example, the circuit element layer PCL can include a semiconductor pattern forming a circuit element, conductive electrodes, and at least one insulating layer therebetween. In addition, the circuit element layer PCL can further include at least one blocking layer for protecting the circuit elements from external invasion and/or at least one planarization layer for planarizing an upper surface of the circuit element layer PCL. A configuration and a structure of the circuit element layer PCL in detail are not specifically limited.

An emission element layer in which the light emitting elements LD are disposed can be disposed on the circuit element layer PCL.

In more detail, a first electrode can be patterned on the circuit element layer PCL. The first electrode can be, for example, an anode electrode 201.

The anode electrode 201 can be formed of a metal material such as chromium, titanium, gold, silver, copper, aluminum and the like. Alternatively, the anode electrode 201 can include a metal material having a high reflectance such as a stacked structure of aluminum (Al) and titanium (Ti)(Ti/Al/Ti), a stacked structure of aluminum (Al) and indium tin oxide (ITO)(ITO/Al/ITO), and an APC alloy. The anode electrode 201 can consist of a single layer or multiple layers, but the embodiments of the present disclosure are not limited thereto.

Such an anode electrode 201 can be patterned in correspondence with each of the pixels PX1 and PX2. In addition, the anode electrode 201 can be electrically connected to a transistor (for example, the driving transistor DT) of each pixel PX1 and PX2 disposed in the circuit element layer PCL through a contact hole and the like.

The bank 211 can be formed on the anode electrode 201. The bank 211 can be formed widely on the substrate 101.

The bank 211 can include an opening overlapping the anode electrode 201. The opening can correspond to, for example, a center region of the anode electrode 201. In such an embodiment, the bank 211 can cover one region of the anode electrode 201, for example, an edge, and expose the remaining other region, for example, a center region, upward through the opening. The exposed region of the anode electrode 201 not covered by the bank 211 can be defined as emission regions EA1 and EA2. An emission layer 202 and a cathode electrode 203, which will be described below, can be sequentially stacked and in direct contact with each other in the exposed region of the anode electrode 201, thereby forming the light emitting element LD.

The bank 211 can be formed of an opaque material so as to prevent light interference between the pixels adjacent to each other. For example, the bank 211 can be formed of an organic material such as a benzocyclobutene resin, a polyimide resin, an acrylic resin, or photosensitive polymer.

Alternatively, the bank 211 can include a black-based material, and can include a light shielding material formed of at least one among, for example, a color pigment (a black pigment), a black dye, organic black, and carbon (black bank). When the bank 211 is formed of the black-based material, the bank 211 can shield external light, and thus, can further improve luminance of the display panel 50. At this instance, the bank 211 can serve to absorb light reflected from a lower side of the bank 211 among light incident from the outside.

In an embodiment of the present disclosure, the bank 211 can be in a multi-layer structure. For example, the bank 211 can include one among an organic layer, and an organic layer having an inorganic coating or an inorganic layer disposed on the organic layer. The inorganic layer can include, for example, silicon oxide SiO2, silicon nitride Si3N4, silicon oxynitride SiON (or Si2N2O), magnesium fluoride MgF2, or combinations thereof. In addition, in an embodiment of the present disclosure in which the bank 211 is formed in a multi-layer structure, a portion of the multi-layer (for example, a lower layer) of the bank 211 can include a black-based material, and a remaining other (for example, an upper layer) can include a transparent material.

The blocking layer 213 can be formed on the bank 211. The blocking layer 213 can be formed in at least one region which includes a center region of the bank 211.

In an embodiment of the present disclosure, the blocking layer 213 can be formed of a non-conductive inorganic material. The non-conductive inorganic material can include, for example, an inorganic silicon-containing material. The silicon-containing material can include, for example, oxides or nitrides of silicon, or combinations thereof, but is not limited thereto.

The metal cup structure layer 310 can be further disposed on the bank 211. For example, the metal cup structure layer 310 can be disposed on the blocking layer 213.

At least two metal cup structure layers 310 can be provided between adjacent pixels PX1 and PX2. The two metal cup structure layers 310 can be formed such that at least a portion thereof overlaps the blocking layer 213. For example, the two metal cup structure layers 310 can be spaced apart from each other at a predetermined interval to cover one side and the other side of the blocking layer 213.

In an embodiment of the present disclosure, the metal cup structure layer 310 can include a lower layer 310A disposed adjacent to the bank 211 and the blocking layer 213, and an upper layer 310B disposed on the lower layer 310A. The lower layer 310A and the upper layer 310B can be formed of a conductive inorganic material. The conductive inorganic material can include a metal-containing material. For example, the metal-containing material includes copper, titanium, aluminum, molybdenum, silver, indium tin oxide, indium zinc oxide, or combinations thereof. However, the material of the metal cup structure layer 310 is not limited thereto.

Such a metal cup structure layer 310 can be configured to receive a low potential driving voltage ELVSS (FIG. 2). For example, the metal cup structure layer 310 can be electrically connected to the low potential driving voltage line PL2 (FIG. 2). For example, the metal cup structure layer 310 can be directly connected to the low potential driving voltage line PL2 disposed in a shorting bar form in the non-display region NA (FIG. 1) of the display panel 50, or can be indirectly connected to the low potential driving voltage line PL2 through a connection electrode and the like. A connection structure of the metal cup structure layer 310 and the low potential driving voltage line PL2 can be described in more detail with reference to the drawings below.

The lower layer 310A of the metal cup structure layer 310 can be formed to cover at least one region of the blocking layer 213. For example, the lower layer 310A can be formed to cover at least a portion of an edge of the blocking layer 213. In an embodiment of the present disclosure, the lower layer 310A can be formed to further cover a portion of an upper surface of the bank 211 which is not covered by the blocking layer 213.

The upper layer 310B of the metal cup structure layer 310 can be formed wider than the lower layer 310A. For example, a lower surface of the upper layer 310B can be formed wider than an upper surface of the lower layer 310A. In such an embodiment of the present disclosure, at least one region of the upper layer 310B can protrude more outward than the lower layer 310A, and can form a shadowing region SA with respect to lower layers, for example, the blocking layer 213.

In other words, the metal cup structure layer 310 can have a form of which a side surface thereof has an inverse taper form. Such a metal cup structure layer 310 can be formed by depositing a construction material of the lower layer 310A and the upper layer 310B and then, patterning the lower layer 310A and the upper layer 310B in the inverse taper form. Alternatively, the metal cup structure layer 310 can be formed by patterning the lower layer 310A and patterning the upper layer 310B on an upper side of the patterned lower layer 310A again.

The blocking layer 213 and the two metal cup structure layers 310 adjacent to each other can form a metal cup hole H surrounded by them. One region of the blocking layer 213 can be exposed upward inside the metal cup hole H. Such a metal cup hole H can trap external materials such as oxygen, moisture, and the like invading through a passivation film 102 and the like which will be described below, and prevent damage to the light emitting element LD due to invasion of the external materials.

A spacer 320 can be further formed on the metal cup structure layer 310. The spacer 320 can be provided to protect the light emitting element LD by preventing direct transfer of external impact to the light emitting element LD. The spacer 320 can be formed of an organic insulating material such as polyimide, polyamide, an acrylic resin, a benzocyclobutene resin, a hexamethyldisiloxane resin, and a phenolic resin, and can be formed as a single-layer or a multi-layer. The spacer 320 can be formed of the same material as the bank 211, but is not limited thereto.

The spacer 320 can be formed to cover at least one region of the upper layer 310B of the metal cup structure layer 310. In an embodiment of the present disclosure, the spacer 320 can further cover the upper surface of the bank 211 which is not covered by the blocking layer 213 and the metal cup structure layer 310. For example, the spacer 320 can extend to the upper surface of the bank 211 from an upper surface of the metal cup structure layer 310. In such an embodiment, the spacer 320 can cover a side surface of the metal cup structure layer 310 which is adjacent to the upper surface of the bank 211.

The spacer 320 may not be formed inside the metal cup hole H. Accordingly, by making the passivation film 102 which will be described below be in direct contact with the inside of the metal cup hole H, the external material invading through the passivation film 102 and the like is efficiently trapped inside the metal cup hole H.

An emission layer 202 can be formed on the anode electrode 201. The emission layer 202 can be formed in at least one region of the bank 211 and the exposed region of the anode electrode 201 not covered by the bank 211.

In an embodiment of the present disclosure, the emission layer 202 can extend to the non-emission region across the emission regions EA1 and EA2. For example, the emission layer 202 can be further formed on the spacer 320, the metal cup structure layer 310, and an exposed region of the blocking layer 213. At this instance, the emission layer 202 can be cut around the edge of the upper layer 310B of the metal cup structure layer 310 because of a low step coverage. Therefore, a portion of the upper surface of the blocking layer 213 formed in the shadowing region SA and a side surface of the metal cup structure layer 310 in contact therewith are not covered by the emission layer 202 and is exposed inside the metal cup hole H, and can come into contact with the cathode electrode 203 which will be described below.

The emission layer 202 can be formed of an organic material which emits light in correspondence with a voltage applied to the anode electrode 201 and the cathode electrode 203 which will be described below. In an embodiment of the present disclosure, the emission layer 202 can emit light in one color among red, green, and blue according to kinds of an organic material. However, the embodiment is not limited thereto, and the emission layer 202 can be configured to emit light in a different color such as white and the like.

In an embodiment of the present disclosure, a common layer can be interposed between the anode electrode 201 and the emission layer 202. The common layer is an organic layer, and for example, can include a hole transport layer HTL, a hole injection layer HIL, an electron transport layer ETL, and/or an electron injection layer EIL, but is not limited thereto.

A second electrode can be formed on the emission layer 202. The second electrode can be the cathode electrode 203. The cathode electrode 203 can include a metal material having a high reflectance such as a stacked structure of aluminum (Al) and titanium (Ti)(Ti/Al/Ti), a stacked structure of aluminum (Al) and indium tin oxide (ITO)(ITO/Al/ITO), and an APC alloy. The cathode electrode 203 can consist of a single layer or multiple layers, but the embodiments of the present disclosure are not limited thereto.

The cathode electrode 203 can be formed wide on the substrate 101. Unlike the emission layer 202, the cathode electrode 203 can be continuously formed without cut-off around the edge of the upper layer 310B of the metal cup structure layer 310 by a high step coverage. Therefore, inside the metal cup hole H, the cathode electrode 203 can be formed to be in contact with an upper surface of the blocking layer 213 not covered by the emission layer 202 and exposed and a side surface of the metal cup structure layer 310 adjacent to the exposed upper surface of the blocking layer 213. In particular, the cathode electrode 203 can be formed to cover a side surface of the lower layer 310A of the metal cup structure layer 310 and the lower surface of the upper layer 310B.

Because the metal cup structure layer 310 is electrically connected to the low potential driving voltage line PL2, the cathode electrode 203 can be electrically connected to the low potential driving voltage line PL2 through the metal cup structure layer 310 and can receive the low potential driving voltage ELVSS. In a structure in which the cathode electrode 203 covers a side surface of the metal cup structure layer 310, an area of electrical contact between the cathode electrode 203 and the metal cup structure layer 310 is very wide, and thus, the low potential driving voltage ELVSS can be efficiently transferred to the cathode electrode 203. Therefore, an IR drop phenomenon generated when the low potential driving voltage ELVSS is applied to the display panel 50 having a large area can be improved, and the low potential driving voltage ELVSS having the same magnitude is stably supplied to the pixels PX1, PX2 and PX3, thereby luminance uniformity between the pixels PX1, PX2 and PX3 can be improved.

The passivation film 102 can be formed on the cathode electrode 203. The passivation film 102 can be a local passivation layer disposed in a region of each pixel PX1 and PX2, or a layer in correspondence therewith.

The passivation film 102 can be formed of an organic material such as an acrylic resin, an epoxy resin, a phenolic resin, a polyamide resin, or a polyimide resin, or an inorganic material such as nitride silicon SiNx, oxide silicon SiOx, silicon oxynitride SiON or aluminum oxide Al2O3, but is not limited thereto. The passivation film 102 can have a structure formed of a single layer or multiple layers.

The passivation film 102 can cover the cathode electrode 203, and can extend along an inner side surface of the metal cup hole H. In such an embodiment, an invasion path of an external material introduced through the passivation film 102 between the adjacent pixels PX1 and PX2 can be blocked by the blocking layer 213 and the metal cup structure layer 310 as illustrated. For example, the external material such as a harmful gas cannot be transferred to the light emitting element LD by being trapped inside the metal cup hole H, and damage of the light emitting element LD can be prevented.

Meanwhile, in a stripe arrangement as illustrated in FIG. 3, a distance between the adjacent pixel columns is relatively close and the distance between the adjacent pixel columns is further narrowed down in the display panel 50 having high image quality and high resolution. Therefore, a lateral leakage current (LLC) can be generated between the pixels PX1, PX2 and PX3 disposed adjacent to each other.

In an embodiment of the present disclosure of FIG. 4, the blocking layer 213 disposed between the metal cup structure layers 310 is formed of a non-conductive inorganic material, and therefore, a path of the lateral leakage current flowing between the adjacent pixels PX1 and PX2 is blocked, and an electrical short and a damage between the pixels PX1 and PX2 can be prevented.

In an embodiment of the present disclosure, a first planarization layer 103 can be further provided. The first planarization layer 103 can planarize a step difference formed by the lower layers and protect the components on a lower side. The first planarization layer 103 can be formed of an organic material including an acrylic resin, an epoxy resin, a phenolic resin, a polyamide resin, or a polyimide resin, but is not limited thereto. The first planarization layer 103 can have a structure formed of a single layer or multiple layers.

In an embodiment of the present disclosure, an inkjet layer, a photoresist, a color filter, or a photosensitive monomer and the like can be further disposed between the passivation film 102 and the first planarization layer 103, but the embodiment is not limited thereto.

FIG. 5 is another example of a cross-sectional view taken along I-I’ line illustrated in FIG. 3. In describing the embodiment of the present disclosure of FIG. 5, the same reference numerals are provided to the components redundant with those of FIG. 4, and a detailed description thereof will be omitted or may be briefly provided.

Referring to FIG. 5, a color filter layer can be further formed on the first planarization layer 103.

The color filter layer can include a buffer layer 401, a color filter 402, and a black matrix 403 formed on the first planarization layer 103. The color filter 402 can block or transmit a certain color from light emitted in the emission region. The black matrix 403 can be disposed between the color filters 402, and can divide each pixel PX, and prevent light interference between the pixels PX adjacent to each other. For example, the color filter 402 can be in contact with each of a side surface and an upper surface of the black matrix 403.

A second planarization layer 404 can be further disposed on the color filter layer. The second planarization layer 404 can serve to planarize a step difference formed by the color filter 402. For example, the second planarization layer 404 can include an organic insulation material.

A touch sensor layer can be formed on the second planarization layer 404.

In more detail, a touch buffer layer 501 can be formed on the second planarization layer 404. The touch buffer layer 501 can be positioned between a touch sensor metal including touch electrodes 502 and 503, and the cathode electrode 203 of the light emitting element LD.

The touch buffer layer 501 can prevent a liquid chemical (a developing solution or an etching solution), used during a process of manufacturing the touch sensor metal disposed on the touch buffer layer 501, or moisture from the outside from invading the emission layer 202 which includes an organic matter. Therefore, the touch buffer layer 501 can prevent damage to the emission layer 202, which is vulnerable to the liquid chemical or moisture.

The touch buffer layer 501 can be formed of an organic insulation material of which formation is possible at a low temperature equal to or below a predetermined temperature (for example, 100° C ) and having a low dielectric constant of 1 to 3 so as to prevent damage of the emission layer 202 which includes an organic matter vulnerable to a high temperature. For example, the touch buffer layer 501 can be formed of an acryl-based, epoxy-based or siloxane-based material. The touch buffer layer 501 formed of an organic insulation material and having a planarization performance can prevent damage of the second planarization layer 404 and breakage of the touch sensor metal on the touch buffer layer 501, due to warping of the display device 1.

According to a mutual-capacitance-based touch sensor structure, the touch electrodes 502 and 503 can be disposed on the touch buffer layer 501, and the touch electrodes 502 and 503 can intersect each other.

A touch electrode connection line can be electrically connected between the touch electrodes 502 and 503. The touch electrodes 502 and 503 can be electrically connected to a touch driver and the like through a touch electrode connection line and the like. A portion of the touch electrode connection line can receive a touch driving signal from a touch driving circuit and transfer it to the touch electrodes 502 and 503, and can transfer a touch sensing signal in the touch electrodes 502 and 503 to the touch driving circuit.

The touch electrode connection line and the touch electrodes 502 and 503 can be provided in different layers with a touch insulating film interposed therebetween. The touch electrode connection line can be disposed to overlap the bank 211, and prevent decline of the aperture ratio. The touch electrode connection line can be formed of a dual line, and at this instance, each layer of the touch electrode connection line can be formed on the touch buffer layer 501 and the touch insulating film, respectively.

A touch protection film 504 can be disposed on the touch electrodes 502 and 503.

In the above embodiments of the present disclosure, a touch sensor layer is disposed on the color filter layer. However, the embodiment is not limited thereto. In other various embodiments of the present disclosure, the color filter layer can be disposed on the touch sensor layer.

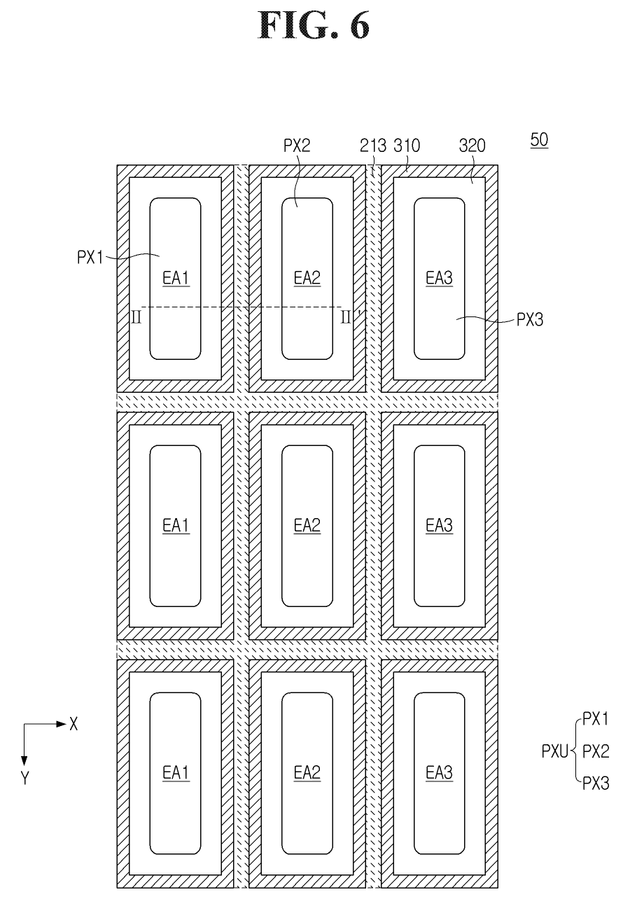

FIG. 6 is a schematic plan view of a display panel according to a second embodiment of the present disclosure.

In comparison with the embodiment of FIG. 3, in an embodiment of FIG. 6, each of the emission regions EA1, EA2 and EA3 can be surrounded by the spacer 320 defining the emission regions EA1, EA2 and EA3. The spacer 320 can be formed in a mesh form surrounding each of the emission regions EA1, EA2 and EA3.

Referring to FIG. 6, the bank 211 can be formed such that at least one region thereof is covered by the spacer 320, and formed to be spaced apart from the emission regions EA1, EA2 and EA3. The bank 211 can be formed to surround a periphery of the emission regions EA1, EA2 and EA3.

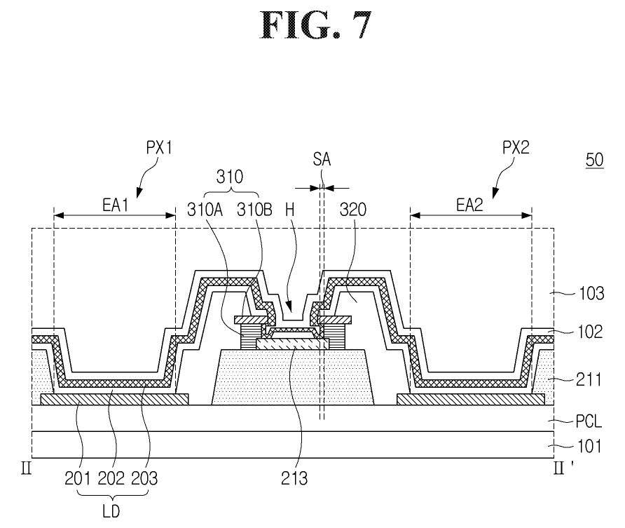

FIG. 7 is an example of a cross-sectional view taken along II-II’ line illustrated in FIG. 6. In describing the embodiment of FIG. 7, the same reference numerals are provided to the components redundant with those of FIG. 4, and a detailed description thereof will be omitted or may be briefly provided.

Referring to FIG. 7, the anode electrode 201 can be patterned in correspondence with each of the emission regions EA1 and EA2. The bank 211 can be spaced apart from the anode electrode 201 on the circuit element layer PCL. Unlike the embodiment of FIG. 4, the bank 211 can be formed not to cover the anode electrode 201. The bank 211 can be formed to surround the patterned anode electrode 201 on the plane, but is not limited thereto.

The blocking layer 213 can be formed on the bank 211. The blocking layer 213 can be formed in at least one region of the bank 211 which includes a center region of the bank 211.

The metal cup structure layer 310 can be formed on the bank 211 and the blocking layer 213. At least two metal cup structure layers 310 can be provided between the pixels PX1 and PX2 adjacent to each other. The two metal cup structure layers 310 can be spaced apart from each other at a predetermined interval on the blocking layer 213.

The blocking layer 213 and the two metal cup structure layers 310 can form a predetermined metal cup hole H surrounded by them. The metal cup hole H can trap external materials such as oxygen, moisture, and the like invading through the passivation film 102 and the like, and prevent damage to the light emitting element LD due to invasion of the external materials.

The spacer 320 can be formed on the metal cup structure layer 310. The spacer 320 can be formed to cover at least one region of the upper layer 310B of the metal cup structure layer 310. In an embodiment of the present disclosure, the spacer 320 can be formed to further cover an upper surface of the bank 211 which is not covered by the blocking layer 213 and a side surface of the metal cup structure layer 310 adjacent to the upper surface of the bank 211.

In an embodiment of the present disclosure in FIG. 7, the spacer 320 can be further formed to cover at least one region of the anode electrode 201. For example, the spacer 320 can be formed to cover an edge of the anode electrode 201 and expose a center region thereof upward. At this instance, the exposed region of the anode electrode 201 not covered by the spacer 320 can be defined as the emission regions EA1 and EA2.

In such an embodiment, the spacer 320 can be further formed to cover a spaced region between the bank 211 and the anode electrode 201 and a side surface of the bank 211 adjacent to the spaced region. As such, when spacing the bank 211 and the anode electrode 201 apart from each other and further disposing the spacer 320 therebetween, invasion of the external materials invading through the bank 211 and the like into the light emitting element LD can be more effectively blocked.

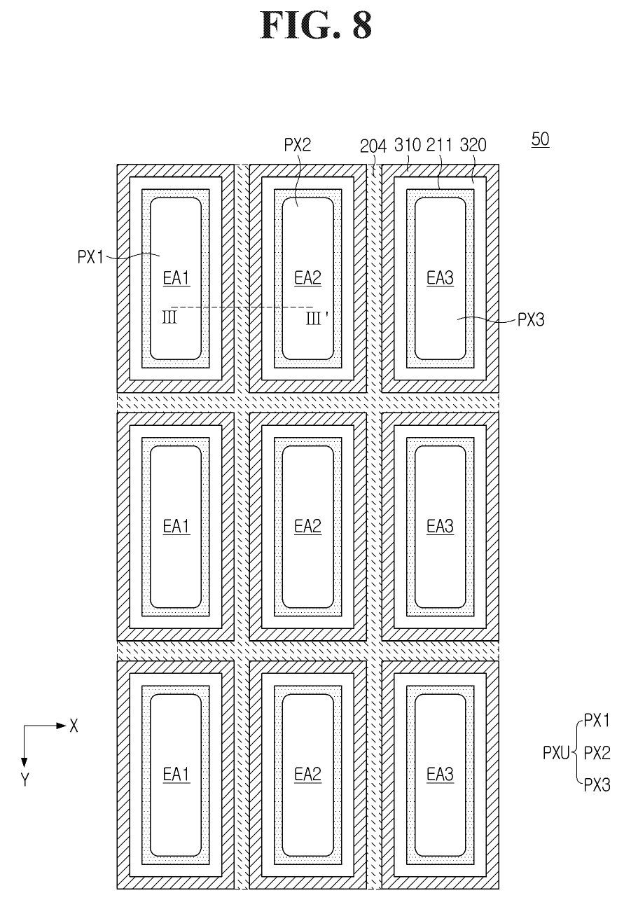

FIG. 8 is a schematic plan view of a display panel according to a third embodiment of the present disclosure.

Referring to FIG. 8, the display panel 50 according to an embodiment of the present disclosure includes a plurality of unit pixels PXU. Each of the unit pixels PXU can include a plurality of pixels PX1, PX2, and PX3 configured to emit light in colors different from one another. In an embodiment of the present disclosure, the plurality of pixels PX1, PX2 and PX3 can display one color among red, green and blue. However, the embodiment is not limited thereto.

In an embodiment of the present disclosure, the pixels PX1, PX2 and PX3 configured to emit light in colors different from one another can be alternately disposed along the first direction X. In addition, the pixels PX1, PX2 and PX3 configured to emit light in the same color can be disposed along the second direction Y generally perpendicular to the first direction.

Like FIG. 3, each of the pixels PX1, PX2 and PX3 can include the emission regions EA1, EA2 and EA3 in correspondence therewith. Each of the emission regions EA1, EA2 and EA3 can be surrounded by the bank 211 defining the emission regions EA1, EA2 and EA3.

A connection electrode 204 and the metal cup structure layer 310 can be formed on the bank 211.

The connection electrode 204 can be formed in at least one region of the bank 211. For example, the connection electrode 204 can have an elongated form extending along the bank 211 along the first direction X. Alternatively, the connection electrode 204 can have a mesh form extending in the first direction X and the second direction Y along the bank 211, but is not limited thereto.

The connection electrode 204 can be provided to electrically connect the cathode electrode 203 of the light emitting element LD and the low potential driving voltage line PL2 (FIG. 2). To this end, the connection electrode 204 can be electrically connected to the low potential driving voltage line PL2.

In the embodiment of the present disclosure with the connection electrode 204 having an elongated extending form, an area of electrical connection between the connection electrode 204 and the cathode electrode 203 is very wide. Therefore, the IR drop phenomenon generated when the low potential driving voltage ELVSS is applied to the display panel 50 having a large area can be improved, and the low potential driving voltage ELVSS having the same magnitude is stably supplied to the pixels PX1, PX2 and PX3, thereby luminance uniformity between the pixels PX1, PX2 and PX3 can be improved.

The metal cup structure layer 310 can be formed on the bank 211 such that at least one region thereof covers the connection electrode 204. For example, the metal cup structure layer 310 can be formed to cover at least a portion of an edge of the connection electrode 204 and expose a center region thereof.

In an embodiment of the present disclosure, at least two metal cup structure layers 310 can be provided between the pixel rows and/or pixel columns adjacent to each other. The at least two metal cup structure layers 310 can be spaced apart from each other at a predetermined interval. At this instance, each of the metal cup structure layers 310 can be configured such that at least one region thereof covers the connection electrode 204. For example, the metal cup structure layers 310 can be configured such that one metal cup structure layer 310 covers at least a portion of an edge on one side of the connection electrode 204, and the other metal cup structure layer 310 covers at least a portion of an edge on the other side of the connection electrode 204. However, the embodiment of the present disclosure is not limited thereto.

The metal cup structure layer 310 can have a form extending along the second direction Y between the pixel columns adjacent to each other. Alternatively, the metal cup structure layer 310 can have a form extending further along the first direction X between pixel rows adjacent to each other, but is not limited thereto.

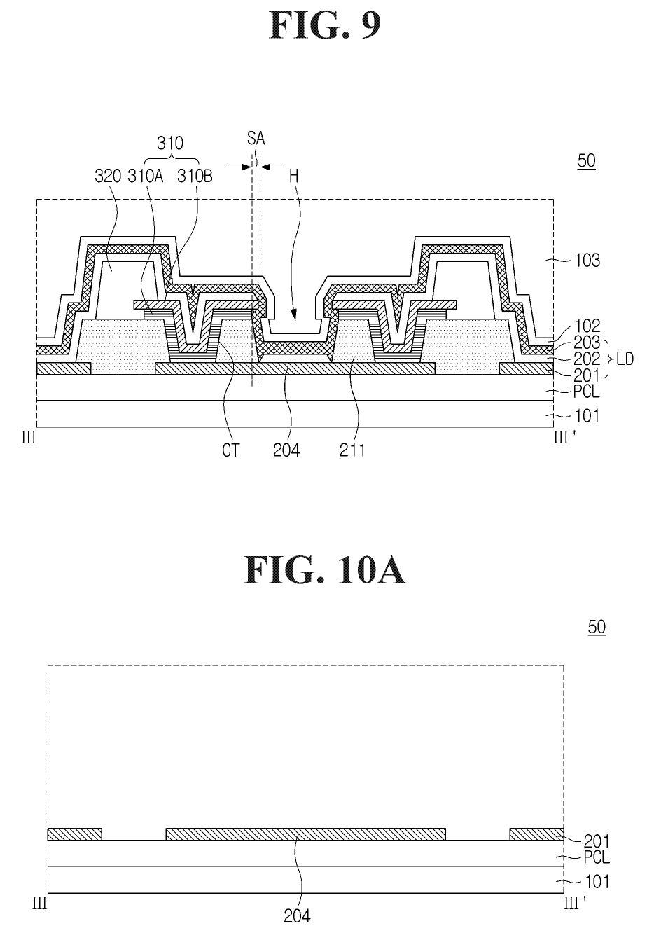

FIG. 9 is an example of a cross-sectional view taken along III-III’ line illustrated in FIG. 8. In describing the embodiment of FIG. 9, the same reference numerals are provided to the components redundant with those of FIG. 4, and a detailed description thereof will be omitted or may be briefly provided.

Referring to FIG. 9, the first electrode can be patterned on the circuit element layer PCL. In addition, the first electrode can be, for example, the anode electrode 201. The anode electrode 201 can be patterned in correspondence with each of the pixels PX1 and PX2.

In addition, the connection electrode 204 can be further formed on the circuit element layer PCL. The connection electrode 204 can be formed of a conductive material. For example, the connection electrode 204 can be formed on the same layer as the anode electrode 201 and formed of the same material as the anode electrode 201, but is not limited thereto.

Such a connection electrode 204 can be configured to receive the low potential driving voltage ELVSS (FIG. 2). For example, the connection electrode 204 can be electrically connected to the low potential driving voltage line PL2 (FIG. 2). For example, the connection electrode 204 can be directly connected to the low potential driving voltage line PL2 in a shorting bar form in the non-display region NA (FIG. 1) of the display panel 50, or can be indirectly connected to the low potential driving voltage line PL2 through an additional connection electrode and the like. A connection structure of the connection electrode 204 and the low potential driving voltage line PL2 can be described in more detail with reference to the drawings below.

The bank 211 can be formed on the anode electrode 201. The bank 211 can be disposed to cover one region of the anode electrode 201, for example, an edge, and expose the remaining other region, for example, a center region of the anode electrode 201. The bank 211 can be formed wide on the substrate 101. A region of the anode electrode 201 which is not covered by the bank 211 and exposed can be defined as the emission region. The emission layer 202 and the cathode electrode 203 can be sequentially stacked on the exposed region of the anode electrode 201 so that they are in direct contact with each other, thereby forming the light emitting element LD.

The metal cup structure layer 310 can be disposed on the bank 211. At least two metal cup structure layers 310 can be provided between the pixels PX1 and PX2 (FIG. 8) adjacent to each other. The two metal cup structure layers 310 can be spaced apart from each other at a predetermined interval on the bank 211.

In an embodiment of the present disclosure, the metal cup structure layer 310 can include the lower layer 310A disposed adjacent to the bank 211, and the upper layer 310B disposed on the lower layer 310A. The lower layer 310A and the upper layer 310B can be formed of a conductive inorganic material. The conductive inorganic material can include a metal-containing material. For example, the metal-containing material includes copper, titanium, aluminum, molybdenum, silver, indium tin oxide, indium zinc oxide, or combinations thereof. However, the material of the metal cup structure layer 310 is not limited thereto.

The lower layer 310A of the metal cup structure layer 310 can overlap at least one region of the connection electrode 204. For example, the lower layer 310A can be formed to overlap at least a portion of an edge of the connection electrode 204.

The upper layer 310B of the metal cup structure layer 310 can be formed wider than the lower layer 310A. For example, a lower surface of the upper layer 310B can be formed wider than an upper surface of the lower layer 310A. In such an embodiment, at least one region of the upper layer 310B can protrude more outward than the lower layer 310A, and can form a shadowing region SA with respect to lower layers, for example, the connection electrode 204.

The metal cup structure layer 310 can be in contact with the connection electrode 204 formed below the bank 211 through a contact hole CT formed in the bank 211. In an embodiment of the present disclosure, the contact hole CT can be formed in a dot form or a stripe form. For example, in correspondence with a form of the connection electrode 204 elongated and extending in the second direction Y, the contact hole can be formed in the bank 211 in an elongated and extending form between the pixel columns adjacent to each other.

The connection electrode 204 and the two metal cup structure layers 310 adjacent to each other can form a metal cup hole H surrounded by them. One region of the connection electrode 204 can be exposed upward inside the metal cup hole H. Such a metal cup hole H can trap external materials such as oxygen, moisture, and the like invading through the passivation film 102 and the like, and prevent damage to the light emitting element LD due to invasion of the external materials.

The spacer 320 can be further formed on the metal cup structure layer 310. The spacer 320 can be formed to cover at least one region of the upper layer 310B of the metal cup structure layer 310. In an embodiment of the present disclosure, the spacer 320 can be formed to further cover an upper surface of the bank 211 which is not covered by the metal cup structure layer 310. For example, the spacer 320 can extend from the upper surface of the metal cup structure layer 310 to the upper surface of the bank 211. In such an embodiment, the spacer 320 can cover a side surface of the metal cup structure layer 310 adjacent to the upper surface of the bank 211.

The spacer 320 is not formed inside the metal cup hole H. Accordingly, by making the passivation film 102 be in direct contact with the inside of the metal cup hole H, the external material invading through the passivation film 102 and the like is efficiently trapped inside the metal cup hole H.

The emission layer 202 can be formed on the anode electrode 201. The emission layer 202 can be formed in at least one region of the bank 211 and a region of the anode electrode 201 not covered by the bank 211 and exposed.

In an embodiment of the present disclosure, the emission layer 202 can extend to the non-emission region across the emission regions EA1, EA2 and EA3. For example, the emission layer 202 can be further formed on the spacer 320, the metal cup structure layer 310, and an exposed region of the connection electrode 204. At this instance, the emission layer 202 can be cut around the edge of the upper layer 310B of the metal cup structure layer 310 because of a low step coverage. Therefore, an inner surface of the metal cup structure layer 310 is not covered by the emission layer 202 and is exposed inside the metal cup hole H, and can come into contact with the cathode electrode 203.

The second electrode can be formed on the emission layer 202. The second electrode can be the cathode electrode 203.

The cathode electrode 203 can be formed wide on the substrate 101. Unlike the emission layer 202, the cathode electrode 203 can be continuously formed without cut-off around the edge of the upper layer 310B of the metal cup structure layer 310 by a high step coverage. Therefore, inside the metal cup hole H, the cathode electrode 203 can be formed to be in contact with an upper surface of the connection electrode 204 not covered by the emission layer 202 and exposed and a side surface of the metal cup structure layer 310 adjacent to the exposed upper surface of the connection electrode 204. In particular, the cathode electrode 203 can be formed to cover a side surface of the lower layer 310A and the lower surface of the upper layer 310B of the metal cup structure layer 310.

Because the metal cup structure layer 310 is electrically connected to the low potential driving voltage line PL2 through the connection electrode 204, the cathode electrode 203 can be electrically connected to the low potential driving voltage line PL2 through the metal cup structure layer 310 and can receive the low potential driving voltage ELVSS. In a structure in which the cathode electrode 203 covers a side surface of the metal cup structure layer 310, an area of electrical contact between the cathode electrode 203 and the metal cup structure layer 310 and an area of electrical contact between the metal cup structure layer 310 and the connection electrode 204 is very wide, and thus, the low potential driving voltage ELVSS can be efficiently transferred to the cathode electrode 203. Therefore, an IR drop phenomenon generated when the low potential driving voltage ELVSS is applied to the display panel 50 having a large area can be improved, and the low potential driving voltage ELVSS having the same magnitude is stably supplied to the pixels PX1, PX2 and PX3, thereby luminance uniformity between the pixels PX1, PX2 and PX3 can be improved.

The passivation film 102 can be formed on the cathode electrode 203. The passivation film 102 can cover the cathode electrode 203, and can extend along an inner side surface of the metal cup hole H. In such an embodiment of the present disclosure, an invasion path of an external material introduced through the passivation film 102 between the adjacent pixels PX1 and PX2 can be blocked by the connection electrode 204 and the metal cup structure layer 310 as illustrated. For example, the external material such as a harmful gas cannot be transferred to the light emitting element LD by being trapped inside the metal cup hole H, and damage of the light emitting element LD can be prevented.

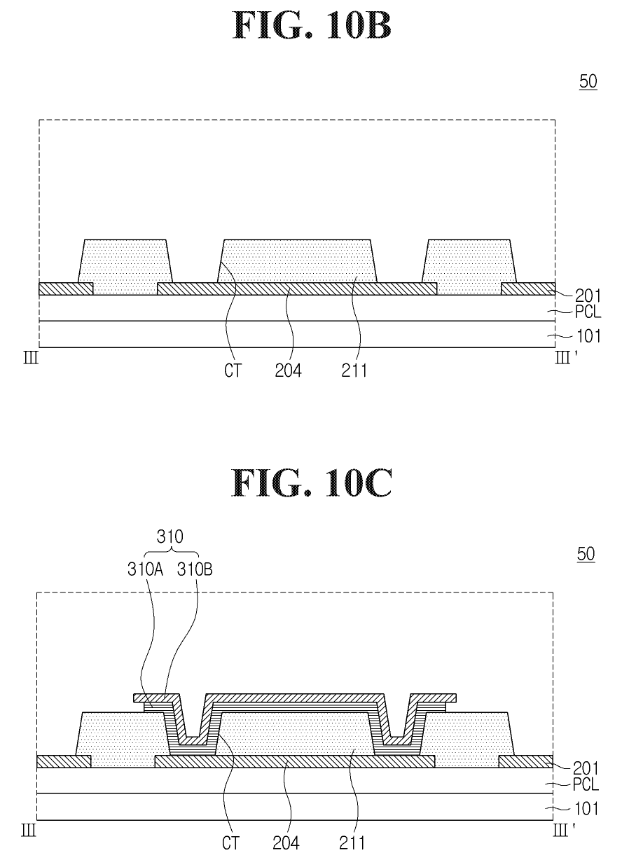

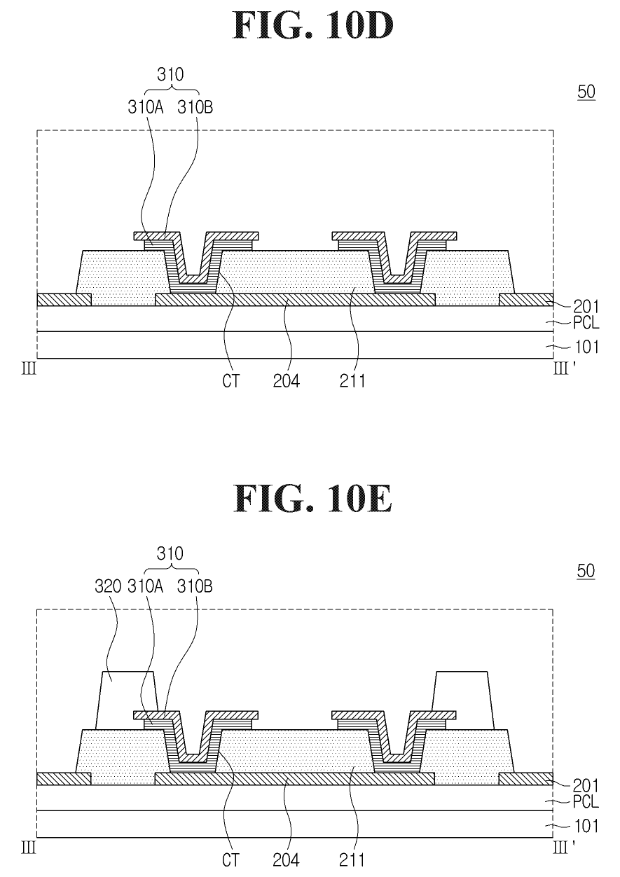

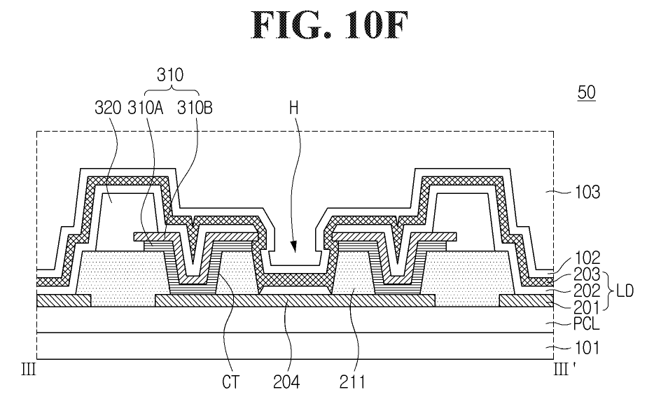

FIGS. 10A-10F are views illustrating a method for manufacturing the display panel illustrated in FIG. 9 according to an embodiment of the present disclosure.

Referring to FIG. 10A, the anode electrode 201 can be formed on the circuit element layer PCL. The anode electrode 201 can be patterned in correspondence with a region of each of the pixels PX1 and PX2 (FIG. 8).

In an embodiment of the present disclosure, the connection electrode 204 can be further formed on the circuit element layer PCL. The connection electrode 204 can be formed to receive the low potential driving voltage ELVSS (FIG. 2), and can be electrically connected to the low potential driving voltage line PL2 through, for example, a contact hole and the like of which illustration is omitted.

Referring to FIG. 10B, the bank 211 can be formed on the anode electrode 201 and the connection electrode 204. For example, a bank material can be deposited on the circuit element layer PCL, and a portion of the bank material can be controlled and patterned through a mask such as a photoresist and the like. The bank 211 can be patterned to cover an edge and expose a center region of the anode electrode 201. In addition, the bank 211 can be patterned to have a contact hole CT which exposes an edge of the connection electrode 204. The patterning can be performed through photolithography, a digital lithography process, or a laser ablation process and the like.

Referring to FIGS. 10C and 10D, the metal cup structure layer 310 can be formed on the bank 211. The metal cup structure layer 310 can be formed such that at least a portion thereof overlaps the contact hole CT, and the metal cup structure layer 310 is in contact with the connection electrode 204 which is exposed upward through the contact hole CT.

In more detail, as illustrated in FIG. 10C, a material of the lower layer and a material of the upper layer can be deposited on the bank 211. In addition, as illustrated in FIG. 10D, the material of the lower layer and the material of the upper layer can be removed through a mask such as a photoresist and the like from the remaining other region except a region around the contact hole CT.

At this instance, the lower layer 310A can be patterned to expose at least one region, for example, a center region of the connection electrode 204 formed therebelow, and the upper layer 310B can be patterned wider than the upper surface of the lower layer 310A to form the shadowing region.

In an embodiment of the present disclosure, a portion of the material of the upper layer can be removed through a dry etching process and the like so that the upper layer 310B can be formed. In addition, a portion of the material of the lower layer can be removed through a wet etching process and the like so that the lower layer 310A can be formed. In an embodiment of the present disclosure, a resist can be a positive resist or a negative resist. At this instance, the etching selectivity and the etching process of the material of the upper layer and the material of the lower layer can be suitably selected so that overhang can be formed between the upper layer 310B and the lower layer 310A.

Referring to FIG. 10E, the spacer 320 can be formed on the bank 211 and the metal cup structure layer 310. The spacer 320 can be formed to cover at least one region of the upper layer 310B of the metal cup structure layer 310. In an embodiment of the present disclosure, the spacer 320 can be patterned to further cover an upper surface of the bank 211 not covered by the metal cup structure layer 310 and a side surface of the metal cup structure layer 310 adjacent to the upper surface of the bank 211.

Referring to FIG. 10F, the emission layer 202, the cathode electrode 203, and the passivation film 102 can be formed on the anode electrode 201, the bank 211, the spacer 320, the metal cup structure layer 310, and the connection electrode 204. In an embodiment of the present disclosure, the cathode electrode 203 formed of ITO and the like can be formed through a sputtering process.

Because of low step coverage, the emission layer 202 is cut around the shadowing region of the metal cup structure layer 310. The cathode electrode 203 and the passivation film 102 can be formed to cover a side surface of the metal cup structure layer 310 because of high step coverage, and extend along an inside of the metal cup hole H.

In the embodiment of the present disclosure illustrated in FIGS. 10A-10F, the method for manufacturing the display panel forms one pixel PX. The operations illustrated in FIGS. 10A-10F can be repeated with respect to additional pixels, and can further form three or more pixels.

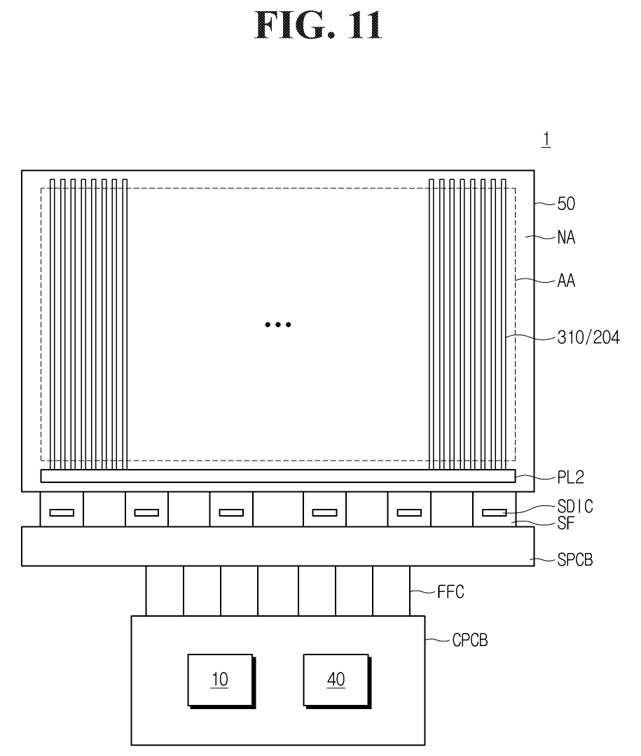

FIG. 11 is a view illustrating an electrical connection relationship of the low potential driving voltage line according to an embodiment of the present disclosure.

Referring to FIG. 11, the display panel 50 can include the display region AA in which the pixels PX are disposed and the non-display region NA around the display region AA. The display region AA can be generally in a quadrangular form or a rectangular form, but is not limited thereto. The non-display region NA can be configured to surround the display region AA, but is not limited thereto.

On one side of the non-display region NA, one or more source driver integrated circuits SDIC included in the data driver 30 (FIG. 1) can be disposed. Each of the source driver integrated circuits SDIC can be mounted in the source film SF, and one side of the source film SF can be electrically connected to the display panel 50. In addition, on an upper portion of the source film SF, lines for electrically connecting the source driver integrated circuits SDICs and the display panel 50 can be disposed.

The display device 1 can include at least one source printed circuit board SPCB and a control printed circuit board CPCB for mounting control parts and various electrical devices therein.

Another side of the source film SF in which the source driver integrated circuit SDIC is mounted can be connected to the at least one source printed circuit board SPCB. For example, one side of the source film SF can be electrically connected to the display panel 50, and another side thereof can be electrically connected to the source printed circuit board SPCB.

The timing controller 10 and the power supply unit 40 can be mounted in the control printed circuit board CPCB. The control printed circuit board CPCB can be electrically connected to the source printed circuit board SPCB through a flexible flat cable FFC or a flexible printed circuit and the like.

A driving voltage output from the power supply unit 40 can be applied to the display panel 50 through the control printed circuit board CPCB, the flexible flat cable FFC, the source printed circuit board SPCB, and lines formed on the source film SF. To this end, an input part of the driving voltage can be disposed adjacent to the source driver integrated circuits SDIC on the display panel 50.

A voltage line electrically connected to the power supply unit 40 can be disposed on the display panel 50. The voltage line can include, for example, a low potential driving voltage line PL2 which receives the low potential driving voltage ELVSS. The low potential driving voltage line PL2 can be formed in, for example, a shorting bar form, in the non-display region NA. For example, the low potential driving voltage line PL2 can be formed in a bar shape elongated and extending along one side surface of the display panel 50 in the non-display region NA adjacent to the source driver integrated circuit SDIC.

A plurality of metal cup structure layers 310 can be formed on the display panel 50. Each of the metal cup structure layers 310 can have a line form elongated and extending across the display region AA.

One side of the metal cup structure layers 310 can be electrically connected to the low potential driving voltage line PL2 disposed in a shorting bar form. When the metal cup structure layer 310 and the low potential driving voltage line PL2 are disposed in different layers, the metal cup structure layer 310 and the low potential driving voltage line PL2 can be electrically connected through a contact hole penetrating one or more insulating layers interposed therebetween. The metal cup structure layer 310 and the low potential driving voltage line PL2 can be connected through one or more connection electrodes interposed therebetween.

In an embodiment of the present disclosure, the low potential driving voltage line PL2 can be formed of a plurality of shorting bars. In such an embodiment, as one or more metal cup structure layers 310 are connected to one shorting bar, the metal cup structure layers 310 can be grouped.

In an embodiment of the present disclosure, another side of the metal cup structure layers 310 can be connected to one another through at least one shorting bar on another side of the metal cup structure layers 310 in correspondence with the low potential driving voltage line PL2. However, the embodiment of the present disclosure is not limited thereto.

In the illustrated embodiment of the present disclosure, instead of the metal cup structure layer 310, the connection electrodes 204 can be electrically connected to the low potential driving voltage line PL2. The connection electrodes 204 can have a line form elongated and extending across the display region AA, like the illustrated metal cup structure layer 310. One side of the connection electrodes 204 can be electrically connected to the low potential driving voltage line PL2 disposed in the shorting bar form.

In such an embodiment of the present disclosure, the metal cup structure layer 310 can be electrically connected to the connection electrodes 204 through a contact hole. The metal cup structure layer 310 can be electrically connected to the low potential driving voltage line PL2 through the connection electrode 204 formed in the display region AA.

The embodiments of the present disclosure have been described with reference to accompanying drawings. Those of ordinary skill in the art will recognize that the present disclosure can be embodied in other specific forms without departing from its spirit or essential characteristics. The described embodiments of the present disclosure are to be considered in all respects only as illustrative and not restrictive. The scope of the present disclosure is therefore indicated by the appended claims rather than by the foregoing description. All changes which come within meaning and range of equivalency of the claims are to be embraced within the scope of the present disclosure.

What is claimed is:

1. A display device, comprising:
a substrate;
an anode electrode formed on the substrate and patterned in correspondence with a plurality of pixels;
a bank formed on the substrate and exposing at least one region of the anode electrode;
an emission layer formed on the anode electrode;
a cathode electrode formed on the emission layer; and
two metal cup structure layers formed on the bank,
wherein a metal cup hole is formed between the two metal cup structure layers spaced apart from each other on the bank.

2. The display device of claim 1, further comprising:
a blocking layer formed on the bank and including a non-conductive inorganic material,
wherein the two metal cup structure layers are formed to cover one region and another region of the blocking layer, respectively.

3. The display device of claim 2,
wherein the blocking layer is formed in a mesh configuration between the two metal cup structure layers to surround at least a part of one or more of the plurality of pixels.

4. The display device of claim 2,
wherein the metal cup hole is surrounded by the blocking layer and the two metal cup structure layers.

5. The display device of claim 1, further comprising:
a spacer formed on at least one of the two metal cup structure layers,
wherein the spacer extends to an upper surface of the bank from an upper surface of the at least one of the two metal cup structure layers.

6. The display device of claim 5,
wherein the spacer further extends from the upper surface of the bank to cover a side surface of the bank and an edge of the anode electrode.

7. The display device of claim 6,
wherein the spacer is further formed between the bank and the anode electrode and formed to cover an upper surface of a circuit element layer not covered by the bank and exposed.

8. The display device of claim 1,
wherein one of the two metal cup structure layers is electrically connected to a low potential driving voltage, and
wherein at least one region of the cathode electrode comes into contact with the one of the two metal cup structure layers in the metal cup hole.

9. The display device of claim 8, comprising:
a low potential driving voltage line in a shorting bar form formed on one side of the substrate,
wherein the one of the two metal cup structure layers or a connection electrode formed on the substrate is electrically connected to the low potential driving voltage line in the shorting bar form on the one side of the substrate.

10. The display device of claim 1, further comprising:
a connection electrode formed on the substrate,
wherein one of the two metal cup structure layers is electrically connected to the connection electrode through a contact hole formed in the bank.

11. The display device of claim 10,
wherein the connection electrode is electrically connected to a low potential driving voltage, and
wherein at least one region of the cathode electrode comes into contact with the one of the two metal cup structure layers in the metal cup hole.

12. The display device of claim 11, comprising:
a low potential driving voltage line in a shorting bar form formed on one side of the substrate,
wherein the one of the two metal cup structure layers or the connection electrode is electrically connected to the low potential driving voltage line in the shorting bar form on the one side of the substrate.

13. The display device of claim 1,
wherein each of at least one of the two metal cup structure layers comprises:
a lower layer formed on the bank; and
an upper layer formed on the lower layer,
wherein a lower surface of the upper layer protrudes more outward than an upper surface of the lower layer, and
wherein the lower layer and the upper layer include a conductive inorganic material.

14. The display device of claim 13,
wherein the emission layer extends into the metal cup hole, and is cut around an edge of the upper layer.

15. The display device of claim 14,
wherein the cathode electrode extends into the metal cup hole, and is formed to come into contact with at least one region of the upper layer and the lower layer in the metal cup hole.

16. A display device, comprising:
a substrate on which a plurality of pixels are formed;
a bank formed on the substrate and configured to define the plurality of pixels; and
two metal cup structure layers formed on the bank,
wherein a metal cup hole is formed between the two metal cup structure layers adjacent to each other on the bank.

17. The display device of claim 16, further comprising:
a blocking layer formed on the bank and having in a mesh configuration to surround each of the plurality of pixels,
wherein the two metal cup structure layers adjacent to each other are formed to cover one region and another region of the blocking layer, respectively, and
wherein the metal cup hole is surrounded by the blocking layer and the two metal cup structure layers adjacent to each other.

18. The display device of claim 16, further comprising:
a connection electrode formed on the substrate,
wherein one of the two metal cup structure layers is electrically connected to the connection electrode through a contact hole formed in the bank.

19. The display device of claim 16, further comprising:
a spacer formed on one of the two metal cup structure layers,
wherein the spacer extends to an upper surface of the bank from an upper surface of the one of the two metal cup structure layers.

20. The display device of claim 19,
wherein the spacer further extends to a side surface of the bank from the upper surface of the bank and is formed to cover an upper surface of a circuit element layer not covered by the bank and exposed.
